(19) United States
(12) Patent Application Publication
(10) Pub. No.: US 2026/0291473 A1
(43) Pub. Date: Sep. 24, 2026

(54) DATA ACQUISITION SYSTEM

(71) Applicant: Cirrus Logic International Semiconductor Ltd., Edinburgh (GB)

(72) Inventors: Lee R. COLEMAN, London (GB); Morgan T. PRIOR, Dunbar (GB); Amr ELSLEHDAR, London (GB)

(73) Assignee: Cirrus Logic International Semiconductor Ltd., Edinburgh (GB)

(21) Appl. No.: 19/085,176

(22) Filed: Mar. 20, 2025

(51) Int. Cl. H03K 5/01; H03K 5/00; H03M 1/12

(52) U.S. Cl. CPC H03K 5/01; H03K 2005/00058; H03M 1/12

(57) ABSTRACT

A data acquisition system comprising: sampling circuitry configured to output data samples; write clock generator circuitry configured to generate a write clock signal having a predefined frequency; read clock generator circuitry configured to generate a read clock signal; spread spectrum modulator circuitry configured to modulate a frequency of the read clock signal, wherein a mean frequency of a resulting spread spectrum modulated read clock signal is equal to the predefined frequency of the write clock signal; a first-in first-out memory (FIFO) configured such that data samples can be written to the FIFO in synchronisation with the write clock signal and data samples can be read from the FIFO in synchronisation with the read clock signal; and control circuitry, wherein the control circuitry is configured to synchronise commencement of data acquisition by the data acquisition system with a transition in the frequency of the spread spectrum modulated read clock signal from the mean frequency.

### FIELD OF THE INVENTION

The present disclosure relates to a data acquisition system.

### BACKGROUND

Data acquisition systems typically sample an electrical signal output by a sensor or transducer that converts a physical quantity into the electrical signal. The electrical signal output by the sensor is typically sampled at a fixed sampling frequency. For example, a system for acquisition of temperature data may include sampling circuitry configured to periodically sample an output of a temperature sensor, while a system for acquisition of image data may include sampling circuitry configured to periodically sample an output of an image sensor, and a system for acquisition of audio data may include sampling circuitry configured to periodically sample an output of an audio transducer.

### SUMMARY

According to a first aspect, the invention provides a data acquisition system comprising: sampling circuitry configured to output data samples; write clock generator circuitry configured to generate a write clock signal having a predefined frequency; read clock generator circuitry configured to generate a read clock signal; spread spectrum modulator circuitry configured to modulate a frequency of the read clock signal, wherein a mean frequency of a resulting spread spectrum modulated read clock signal is equal to the predefined frequency of the write clock signal; a first-in first-out memory (FIFO) configured such that data samples can be written to the FIFO in synchronisation with the write clock signal and data samples can be read from the FIFO in synchronisation with the read clock signal; and control circuitry, wherein the control circuitry is configured to synchronise commencement of data acquisition by the data acquisition system with a transition in the frequency of the spread spectrum modulated read clock signal from the mean frequency.

The transition in the frequency of the spread spectrum modulated read clock signal may be a downward transition in the frequency of the spread spectrum modulated read clock signal from the mean frequency.

The control circuitry may be configured to trigger data acquisition by the data acquisition system responsive to detection of the transition.

The control circuitry may be configured to detect the transition based on a signal indicative of a spread spectrum modulation frequency received from the spread spectrum modulator circuitry.

The control circuitry may be configured to: determine, based on the received signal indicative of a spread spectrum modulation frequency, an instantaneous frequency of the spread spectrum modulated read clock signal; compare a value of the determined instantaneous frequency of the spread spectrum modulated read clock signal to a value of the mean frequency of the spread spectrum modulated read clock signal; and responsive to detecting that the value of instantaneous frequency of the spread spectrum modulated read clock signal has fallen below the value of the mean frequency of the spread spectrum modulated read clock signal, trigger data acquisition by the data acquisition system.

Alternatively, the control circuitry may be configured to: determine, based on the received signal indicative of a spread spectrum modulation frequency, an instantaneous frequency of the spread spectrum modulated read clock signal; compare a value of the determined instantaneous frequency of the spread spectrum modulated read clock signal to a value of the mean frequency of the spread spectrum modulated read clock signal; and responsive to detecting that the value of instantaneous frequency of the spread spectrum modulated read clock signal has risen above the value of the mean frequency of the spread spectrum modulated read clock signal, trigger data acquisition by the data acquisition system.

The controller may be configured to activate or enable the sampling circuitry to trigger data acquisition by the data acquisition system.

The sampling circuitry may comprise analog to digital converter (ADC) circuitry configured to periodically sample a continuous input signal to generate output data samples.

The control circuitry may be configured to trigger data acquisition by the data acquisition system on detection of the transition by enabling or activating the ADC circuitry.

The data acquisition system may further comprise sample clock generator circuitry configured to supply a sample clock signal to the ADC circuitry.

The control circuitry may be configured to trigger data acquisition by the data acquisition system on detection of the transition by enabling or activating the sample clock generator circuitry.

The control circuitry may be configured to prevent reading of a data sample from the FIFO for a predetermined delay period following detection of the transition.

The control circuitry may be configured to, responsive to receiving a signal indicating that data acquisition is to commence: trigger modulation of the read clock signal by the spread spectrum modulator circuitry; and activate or enable the sampling circuitry to trigger data acquisition by the data acquisition system.

The sampling circuitry may comprise analog to digital converter (ADC) circuitry configured to periodically sample a continuous input signal to generate output data samples.

The control circuitry may be configured to enable or activate the ADC circuitry to trigger data acquisition by the data acquisition system.

The data acquisition system may further comprise sample clock generator circuitry configured to supply a sample clock signal to the ADC circuitry.

The control circuitry may be configured to enable or activate the sample clock generator circuitry to enable or activate the ADC circuitry.

The control circuitry may be configured to prevent reading of a data sample from the FIFO for a predetermined delay period following triggering modulation of the read clock signal by the spread spectrum modulator circuitry.

According to a second aspect, the invention provides a data acquisition system comprising: sampling circuitry configured to output data samples; write clock generator circuitry configured to generate a write clock signal having a predefined frequency; read clock generator circuitry; spread spectrum modulator circuitry configured to modulate a frequency of the read clock signal to generate a spread spectrum modulated read clock signal, wherein a mean frequency of the spread spectrum modulated read clock signal is equal to the predefined frequency of the write clock signal; a first-in first-out memory (FIFO) configured such that data samples can be written to the FIFO in synchronisation with the write clock signal and data samples can be read from the FIFO in synchronisation with the read clock signal; and control circuitry, wherein the control circuitry is configured to trigger data acquisition by the data acquisition system responsive to detection of a transition in the frequency of the spread spectrum modulated read clock signal from the mean frequency.

According to a third aspect, the invention provides a data acquisition system comprising: sampling circuitry configured to output data samples; write clock generator circuitry configured to generate a write clock signal having a predefined frequency; read clock generator circuitry; spread spectrum modulator circuitry operable to modulate a frequency of the read clock signal to generate a spread spectrum modulated read clock signal, wherein a mean frequency of the spread spectrum modulated read clock signal is equal to the predefined frequency of the write clock signal; a first-in first-out memory (FIFO) configured such that data samples can be written to the FIFO in synchronisation with the write clock signal and data samples can be read from the FIFO in synchronisation with the read clock signal; and control circuitry, wherein the control circuitry is configured to trigger operation of the spread spectrum modulator responsive to receiving a signal indicating that data acquisition is to commence.

According to a fourth aspect, the invention provides an integrated circuit implementing the data acquisition system of the first, second or third aspect.

According to a fifth aspect, the invention provides a host device comprising the data acquisition system of the first, second or third aspect, wherein the host device comprises a laptop, notebook, netbook or tablet computer, a gaming device, a games console, a controller for a games console, a virtual reality (VR) or augmented reality (AR) device, a scanner, a mobile telephone, a portable audio player, a portable device, an accessory device for use with a laptop, notebook, netbook or tablet computer, a gaming device, a games console a VR or AR device, a mobile telephone, a portable audio player or other portable device.

According to a sixth aspect, the invention provides a data acquisition system comprising: sampling circuitry configured to sample an input signal to generate output data samples; an asynchronous first-in first-out memory (FIFO) for receiving data samples from the sampling circuitry; and control circuitry, wherein the control circuitry is configured to, responsive to receiving a signal indicating that data acquisition is to commence, delay generation of output data samples by the sampling circuitry until the FIFO can receive the output data samples without risk of FIFO overrun or FIFO underrun.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the invention will now be described, strictly by way of example only, with reference to the accompanying drawings, of which:

FIG. 1 is a schematic representation of an example data acquisition system;

FIG. 2 shows frequencies of a write clock signal and a read clock signal used in the data acquisition system of FIG. 1 over time;

FIG. 3 is a schematic representation of an example data acquisition system according to the present disclosure;

FIG. 4 shows a start point for data acquisition in the example data acquisition system of FIG. 3;

FIG. 5 is a schematic representation of a further example data acquisition system according to the present disclosure;

FIG. 6 shows a start point for data acquisition and a start point for spread spectrum modulation in the further example data acquisition system of FIG. 5.

FIG. 7 shows a start point for data acquisition, a start point for spread spectrum modulation, and a delay to the start of a read operation in a further example; and

FIG. 8 shows a start point for data acquisition and a delay to the start of a read operation in a further example.

### DETAILED DESCRIPTION

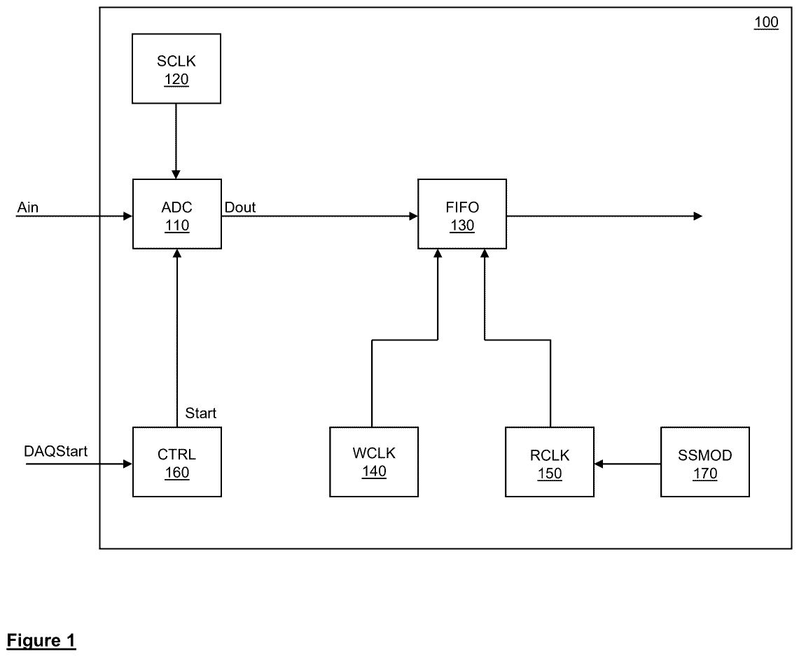

FIG. 1 is a schematic representation of an example data acquisition system.

The data acquisition system, shown generally at 100 in FIG. 1, comprises, in this example, analog to digital converter (ADC) circuitry 110 configured to receive a continuous analog electrical input signal Ain indicative or representative of a physical quantity such as a temperature, an intensity and/or frequency of light, a loudness and/or frequency or the like, and to output digital data samples Dout, each representing an instantaneous value of the analog input signal Ain.

The ADC circuitry 110 receives a sample clock signal from sample clock generator circuitry 120 at a sampling frequency fs, which defines the frequency at which the ADC circuitry 110 samples the analog input signal Ain to generate the output digital data samples Dout.

An output of the ADC circuitry 110 is coupled to an input of a first-in, first-out memory (hereinafter referred to as a FIFO) 130 such that the data samples Dout by the ADC circuitry 110 can be supplied to the FIFO 130.

The FIFO 130 receives a write clock signal from write clock generator circuitry 140 at a fixed frequency fwclk, which may be equal to or otherwise related to (e.g. a multiple of) the sampling frequency fs of the sample clock generator circuitry 120. The frequency fwclk of the write clock signal defines the frequency at which data samples output by the ADC circuitry 110 are written to the FIFO 130.

The FIFO 130 also receives a read clock signal from read clock generator circuitry 150 at a frequency frclk, which defines the frequency at which data samples are read from the FIFO 130.

As will be appreciated by those of ordinary skill in the art, the FIFO 130 is therefore an asynchronous FIFO, as read and write operations are governed by separate clocks.

The data acquisition system 100 further includes control circuitry 160 configured to control operation of the ADC circuitry 110. In response to receiving a signal DAQStart (e.g. from a controller or processor of a host device that incorporates the data acquisition system 100) indicating that data acquisition is to commence, the control circuitry 160 transmits a Start signal to the ADC circuitry 110 to activate or enable the ADC circuitry 110, to cause the ADC circuitry 110 to commence outputting data samples.

In an alternative configuration (not shown in FIG. 1), the control circuitry 160 may transmit the Start signal to the sample clock generator circuitry 120 to enable or activate the sample clock generator circuitry 120, to cause the sample clock generator circuitry 120 to commence outputting the sample clock signal, which has the effect of enabling or activating the ADC circuitry 110.

The use of digital clock signals with fixed frequencies gives rise to a risk of electromagnetic interference (EMI), as the energy of the clock signal is concentrated at the frequency of the clock signal and harmonics of the frequency of the clock signal. Such energy may be radiated, causing interference with nearby systems and devices.

To mitigate the risk of EMI, the data acquisition system 100 includes spread spectrum modulator circuitry 170 configured to modulate the frequency of the read clock signal using a spread spectrum modulation signal having a spread spectrum modulation frequency, such that the instantaneous frequency of the read clock signal varies over time about (above and below) a mean frequency. The mean frequency of the spread spectrum modulated read clock signal is equal to the fixed frequency fwclk of the write clock signal.

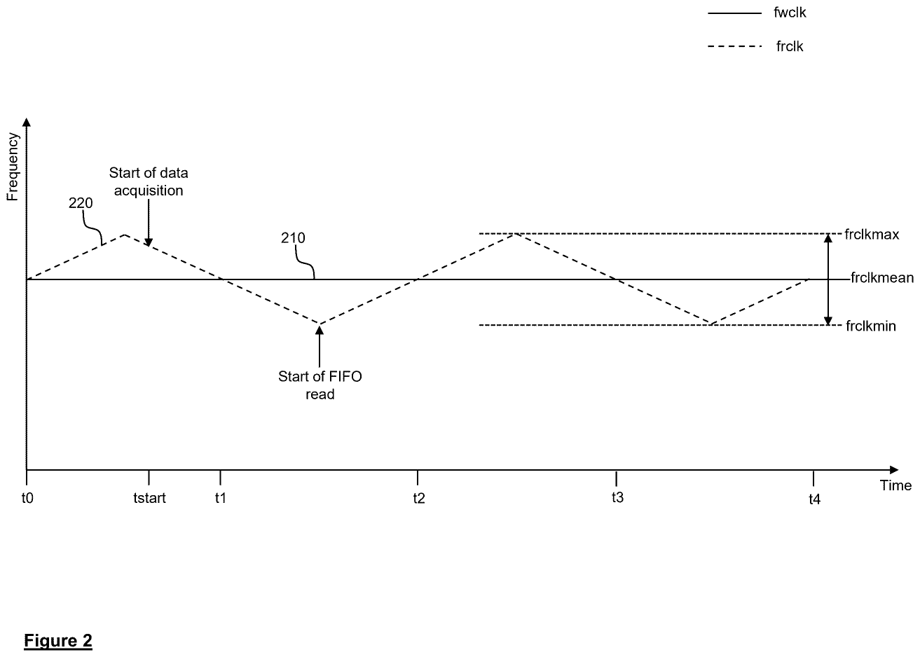

FIG. 2 shows the fixed frequency of the write clock signal 210 and the instantaneous frequency of the spread spectrum modulated read clock signal 220 over time. As can be seen from FIG. 2, the instantaneous frequency frclk of the spread spectrum modulated read clock signal 220 varies over time about a mean frequency frclkmean, between a minimum frequency frclkmin and a maximum frequency frclkmax. The mean frequency frclkmean of the spread spectrum modulated read clock signal 220 is equal to the fixed frequency fwclk of the write clock signal 210.

The difference between frclkmax and frclkmin may be referred to as the spread spectrum magnitude. The magnitude of the difference between frclkmax and frclkmean is equal to the magnitude of the difference between frclkmean and frclkmin, i.e. frclkmax−frclkmean=frclkmean−frclkmin. Thus, a maximum positive deviation of the instantaneous frequency frclk of the spread spectrum modulated read clock signal 220 from its mean frequency frclkmean is equal to a maximum negative deviation of the instantaneous frequency frclk of the spread spectrum modulated read clock signal 220 from its mean frequency frclkmean.

Further, a magnitude of a rate of change of the frequency frclk of the spread spectrum modulated read clock signal 220 is constant, such that, for example, the rate of change of the frequency frclk of the spread spectrum modulated read clock signal 220 as it decreases from frclkmax to frclkmin is equal in magnitude (but opposite in sign) to the rate of change of the frequency frclk of the spread spectrum modulated read clock signal 220 as it increase from frclkmin to frclkmax.

FIG. 2 shows two complete modulation cycles of the spread spectrum modulated read clock signal 220: a first modulation period starting at a time t0 and ending at a time t2 and a second modulation period starting at the time t2 and ending at a time t4.

As a result of this variation in the instantaneous frequency frclk of the spread spectrum modulated read clock signal, the energy of the read clock signal 220 is distributed over the range of frequencies between frclkmin and frclkmax (and their harmonics), thus reducing the magnitude of energy radiated from the system 100 at any given frequency, which in turn reduces the risk of EMI from the system 100 at any given frequency, in comparison to an arrangement that uses a fixed read clock frequency.

As will be appreciated by those of ordinary skill in the art, during periods in which the frequency frclk of the spread spectrum modulated read clock signal 220 is greater than the fixed frequency fwclk of the write clock signal 210 (e.g. the period between times t0 and t1 in FIG. 2), the FIFO 130 empties, as data samples are read from it more frequently than new data samples are written to it.

Conversely, during periods in which the frequency frclk of the spread spectrum modulated read clock signal 220 is less than the fixed frequency fwclk of the write clock signal 210 (e.g. the period between times t1 and t2 in FIG. 2), the FIFO 130 fills, as new data samples are written to it more frequently than data samples are read from it.

In the data acquisition system 100, the spread spectrum modulator circuitry 170 operates continuously to modulate the frequency of the read clock signal. Data acquisition to generate and write data samples to the FIFO 130 may be started at any point in the modulation period of the spread spectrum modulated read clock signal 220. For example, data acquisition operation may be commenced at a time tstart (shown in FIG. 2), responsive to the control circuitry 160 receiving the signal DAQStart.

To avoid inaccuracy in the data acquisition system 100 of FIG. 1 arising from lost data samples, reading of data samples from the FIFO 130 cannot start until the FIFO 130 is half full. This ensures that there are sufficient data samples in the FIFO 130 to be read if the frequency frclk of the spread spectrum modulated read clock signal 220 is greater than the fixed frequency fwclk of the write clock signal 210, and that there is sufficient capacity in the FIFO 130 for new data samples to be written without overwriting existing data samples that have not been read if the frequency frclk of the spread spectrum modulated read clock signal 220 is less than the fixed frequency fwclk of the write clock signal 210.

Delaying reading of data samples from the FIFO 130 in this way thus ensures that FIFO underrun and FIFO overrun conditions can be avoided. A FIFO underrun condition is a condition in which there are insufficient data samples in the FIFO 130 to be read in the period in which the frequency frclk of the spread spectrum modulated read clock signal 220 is greater than the fixed frequency fwclk of the write clock signal 210. A FIFO overrun condition is a condition in which new data samples cannot be written to the FIFO 130 in the period in which the fixed frequency fwclk of the write clock signal 210 is greater than the frequency frclk of the spread spectrum modulated read clock signal 220 because there is insufficient free space in the FIFO 130 to write the new samples to the FIFO 130 without overwriting existing data samples stored in the FIFO 130.

As will be appreciated by those of ordinary skill in the art, this approach requires the FIFO 130 to be of sufficient depth (i.e., have sufficient capacity) to accommodate the variation in the frequency of the spread spectrum modulated read clock signal, and thus the FIFO 130 must be relatively large. In an integrated circuit implementation of the system 100, a relatively large FIFO 130 requires a correspondingly relatively large area of silicon, which increases the size and cost of the IC. Additionally, this approach imposes restrictions on the spread spectrum amplitude that can be applied for a given depth of the FIFO 130.

The present disclosure proposes alternative approaches in which commencement of data acquisition by enabling or activating the ADC circuitry 110 (following a signal to commence data acquisition) is synchronised or aligned in time with a downward transition in the frequency of the spread spectrum modulated read clock signal from its mean frequency to a frequency less than its mean frequency, or with an upward transition in the frequency of the spread spectrum modulated read clock signal from its mean frequency to a frequency greater than its mean frequency.

After a downward transition in the frequency frclk of the spread spectrum modulated read clock signal the FIFO 130 starts to fill up on commencement of data acquisition, because the frequency frclk of the spread spectrum read clock signal is less than the frequency fwclk of the write clock signal. The FIFO 130 continues to fill up until the point at which the frequency frclk of the spread spectrum read clock signal increases above its mean frequency frclkmean, at which point the FIFO 130 starts to empty, because the frequency frclk of the spread spectrum read clock signal is greater than the frequency fwclk of the write clock signal.

Provided the spread spectrum modulation is symmetrical around the mean frequency frclkmean of the spread spectrum modulated read clock signal (i.e. provided frclkmax−frclkmean=frclkmean−frclkmin), the FIFO 130 never empties completely, because the frequency frclk of the spread spectrum modulated read clock signal again falls below its mean frequency frclkmean before the FIFO 130 empty completes, at which point the FIFO 130 begins to fill again, as data samples are written to it more frequently than they are read from it. Data acquisition can thus continue indefinitely.

Synchronising or aligning the commencement of data acquisition with a downward transition in the frequency of the spread spectrum modulated read clock signal in this way prevents FIFO underrun or FIFO overrun conditions that may otherwise arise, causing inaccuracy or loss of data samples, due to the difference between the frequency fwclk of the write clock signal and the frequency frclk of the read clock signal without the need for excessive depth of the FIFO 130.

This approach thus permits a reduction in the depth of the FIFO 130, in comparison to the approach described above with reference to FIGS. 1 and 2, as it is not necessary for the FIFO 130 to be half-full before a read operation can commence, and also permits a greater magnitude of spread spectrum modulation to be applied to the read clock signal for a given depth of the FIFO 130.

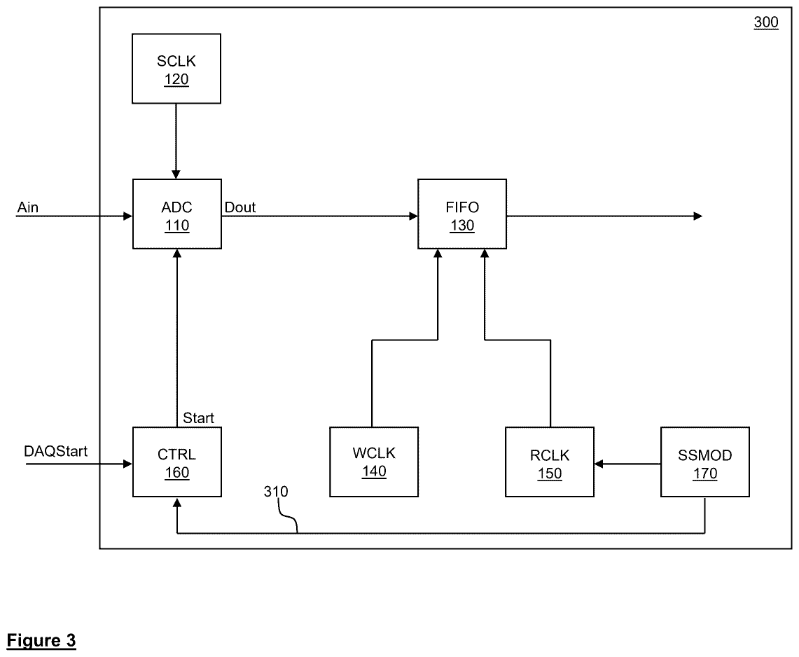

FIG. 3 is a schematic representation of an example of a data acquisition system according to the present disclosure.

The data acquisition system, shown generally at 300 in FIG. 3, has many features in common with the data acquisition system 100 of FIG. 1. Such common features are denoted by common reference numerals in FIGS. 1 and 3 and will not be described again in detail here for the sake of clarity and brevity.

The data acquisition system 300 of FIG. 3 differs from the data acquisition system 100 of FIG. 1 in that the data acquisition system 300 includes a feedback signal path 310 from the spread spectrum modulator circuitry 170 to the control circuitry 160.

The spread spectrum modulator circuitry 170 transmits a signal indicative of the spread spectrum modulation frequency of the spread spectrum modulation signal to the control circuitry 160 via the feedback signal path 310. The control circuitry 160 transmits the Start signal to trigger output of data samples by the ADC circuitry 110 based on this signal (after receiving the signal DAQStart indicating that data acquisition is to commence).

Specifically the control circuitry 160 is configured to determine (in response to receiving the signal DAQStart), based on the signal indicative of the spread spectrum modulation frequency received from the spread spectrum modulator circuitry 170, the instantaneous frequency frclk of the spread spectrum modulated read clock signal. The control circuitry 160 is further configured to compare a value of the determined instant instantaneous frequency frclk of the spread spectrum modulated read clock signal to a value of the mean frequency frclkmean of the spread spectrum modulated read clock signal.

In response to detecting, based on this comparison, a downward transition in the instantaneous frequency frclk of the spread spectrum modulated read clock signal from its mean frequency frclkmean (i.e. detecting that the value of the instantaneous frequency frclk has fallen below the value of the mean frequency frclkmean), the control circuitry 160 transmits the Start signal to the ADC circuitry 110 or to the sample clock generator circuitry 120 to enable or activate the ADC circuitry 110 to allow the ADC circuitry 110 to begin outputting data samples to the FIFO 130.

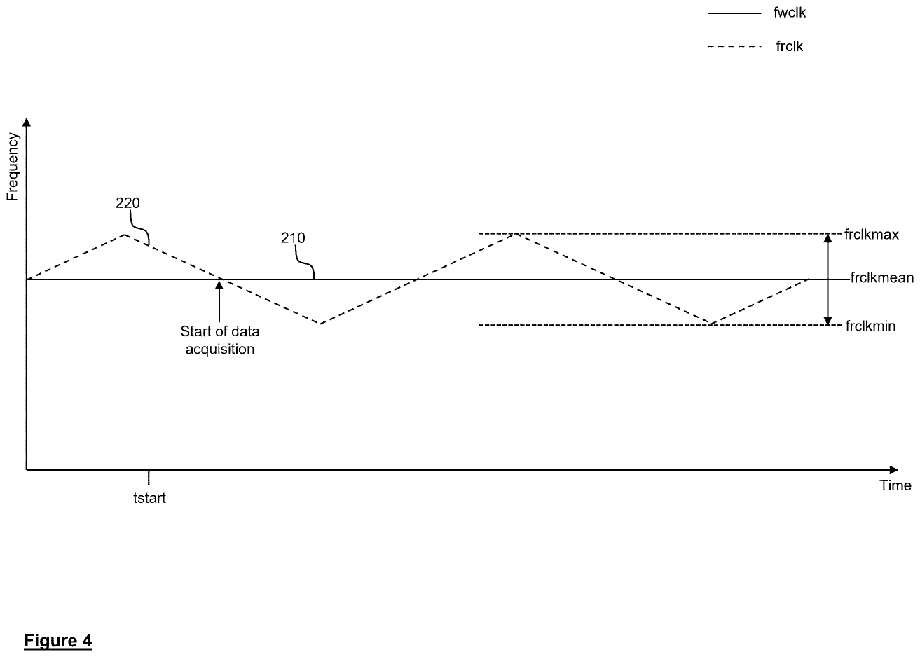

Consequently, in the data acquisition system 300 of FIG. 3 the start of data acquisition is not triggered by the control circuitry 160 receiving the signal DAQStart at time tstart (as in the data acquisition system 100 of FIG. 1), but is instead synchronised or aligned in time with the downward transition in the frequency frclk of the spread spectrum modulated read clock signal, as shown in FIG. 4. As a result, data acquisition starts when the FIFO 130 is filling, because at that point in time the frequency fwclk of the write clock signal is greater than the frequency frclk of the spread spectrum modulated read clock signal.

Thus, there is no need for a delay in starting a read operation to read data samples from the FIFO 130 after the start of data acquisition, because new data samples are written to the FIFO 130 more frequently than stored data samples are read from the FIFO 130, so there is no risk that a read operation will read invalid data from the FIFO 130 because the FIFO 130 is empty.

This in turn allows the depth of the FIFO 130 to be reduced, in comparison to the system 100 described above with reference to FIGS. 1 and 2, as it is not necessary for the FIFO 130 to be half-full before a read operation can commence, and also permits a greater magnitude of spread spectrum modulation to be applied to the read clock signal for a given depth of the FIFO.

As will be appreciated by those of ordinary skill in the art, in the data acquisition system 300 of FIG. 3, the control circuitry 160 is configured to, responsive to receiving the signal DAQStart, delay the generation of output data samples by the sampling circuitry (the ADC circuitry 110 in this example) until the FIFO 130 can receive the output data samples without risk of FIFO overrun or FIFO underrun.

In some examples, a small delay of a predefined duration may be implemented following detection of the downward transition in the frequency frclk of the spread spectrum modulated read clock signal before a read operation is permitted, to allow one or more data samples to be written to the FIFO 130 before a read operation commences. In such examples, the control circuitry 160 may maintain the read clock generator circuitry 150 in a deactivated or disabled state until a predefined delay period has elapsed after detection of the downward transition in the frequency frclk of the spread spectrum modulated read clock signal (or after the Start signal has been transmitted to the ADC circuitry 110 or the sample clock generator circuitry 120). Once the predefined delay period has elapsed, the control circuitry 160 may activate or enable the read clock generator circuitry 150 (e.g. by transmitting an activate or enable signal to the read clock generator circuitry 150) to permit read operations to be performed.

The value of the mean frequency frclkmean may be stored in a memory or register of the control circuitry 160, for example. Alternatively, as the mean frequency frclkmean of the spread spectrum modulated read clock signal is equal to the fixed frequency of the fwclk of the write clock signal, the value of the fixed frequency of the fwclk of the write clock signal may be stored in a memory or register of the control circuitry 160, and the control circuitry 160 may compare the value of the determined instant instantaneous frequency frclk of the spread spectrum modulated read clock signal to this stored value to detect the downward transition in the instantaneous frequency frclk of the spread spectrum modulated read clock signal from its mean frequency frclkmean.

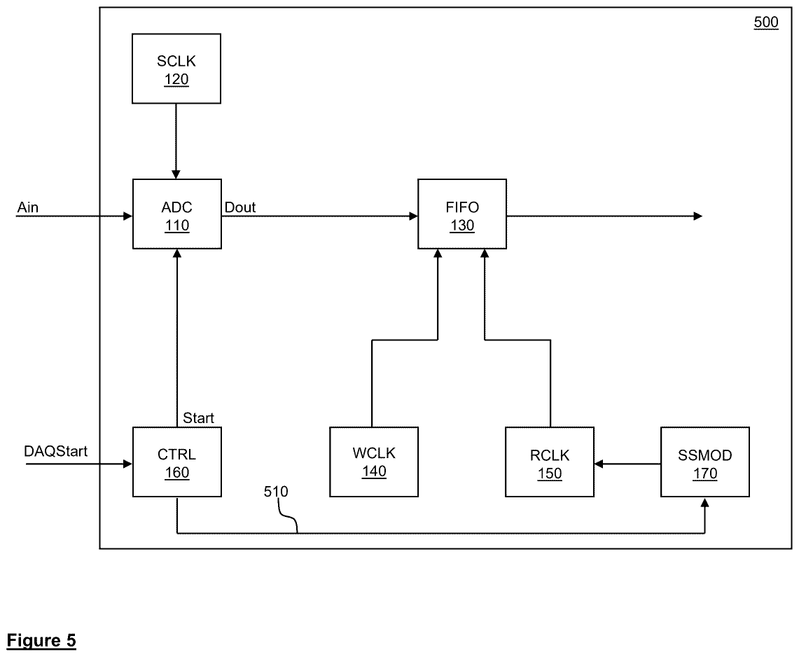

FIG. 5 is a schematic representation of an alternative data acquisition system according to the present disclosure.

The data acquisition system, shown generally at 500 in FIG. 5, has many features in common with the data acquisition system 100 of FIG. 1. Such common features are denoted by common reference numerals in FIGS. 1 and 5 and will not be described again in detail here for the sake of clarity and brevity.

The data acquisition system 500 of FIG. 5 differs from the data acquisition system 100 of FIG. 1 in that the data acquisition system 500 includes a control signal path 510 from the control circuitry 160 to the spread spectrum modulator circuitry 170.

The control circuitry 160 of the data acquisition system 500 of FIG. 5 is configured to transmit a Start signal to the ADC circuitry 110 (or to the sample clock generator circuitry 120) to activate or enable the ADC circuitry 110, to cause the ADC circuitry 110 to commence outputting data samples, in response to receiving a signal DAQStart (e.g. from a controller or processor of a host device that incorporates the data acquisition system 100) indicating that data acquisition is to commence.

The control circuitry 160 is further configured to transmit a modulation control signal to the spread spectrum modulator circuitry 170, in response to receiving the signal DAQStart, to activate or enable the spread spectrum modulator circuitry 170. In response to receiving the modulation control signal from the control circuitry 160, the spread spectrum modulator circuitry 170 is activated or enabled and begins modulating the frequency of the read clock signal generated by the read clock generator circuitry 150 using the spread spectrum modulation signal.

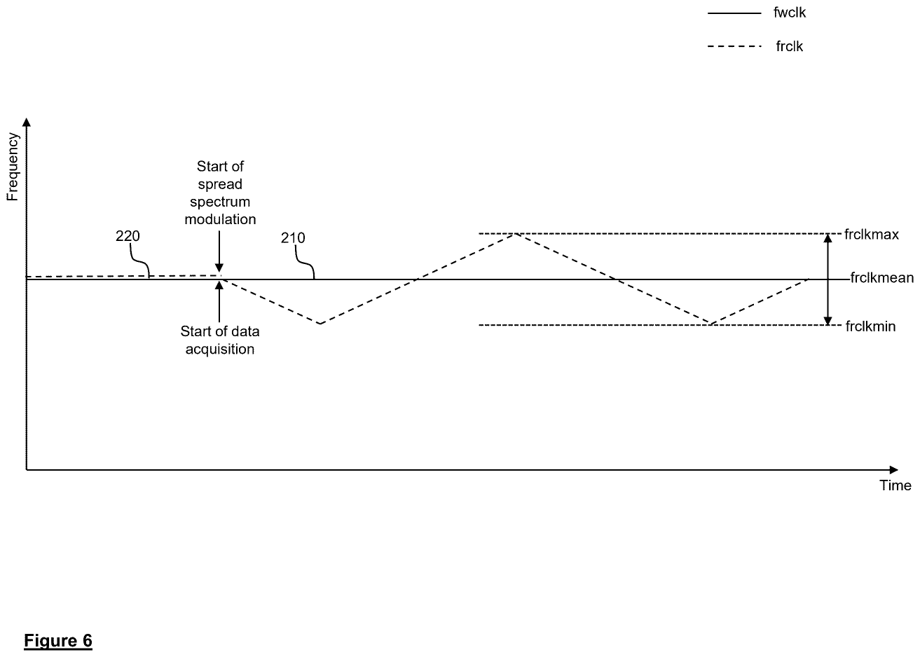

Prior to the activation or enabling of the spread spectrum modulator circuitry 170, the read clock signal is unmodulated, and its frequency is constant and equal to the frequency fwclk of the write clock signal (which, as explained above, is equal to the mean frequency frclkmean of the spread spectrum modulated read clock signal). As shown in FIG. 6, on commencement of the spread spectrum modulation of the frequency of the read clock signal, there is a downward transition in the frequency of the resulting spread spectrum modulated read clock signal, i.e. the frequency frclk falls below the mean frequency frclkmean. Thus, the start of data acquisition is synchronised or aligned in time with the downward transition in the frequency frclk of the spread spectrum modulated read clock signal.

As in the example data acquisition system 300 described above with reference to FIGS. 3 and 4, a consequence of the synchronisation of the start of data acquisition with the downward transition in the frequency frclk of the read clock is that data acquisition starts when the FIFO 130 is filling, because at that point in time the frequency fwclk of the write clock signal is greater than the frequency frclk of the spread spectrum modulated read clock signal. There is thus no need for a delay in starting a read operation to read data samples from the FIFO 130 after the start of data acquisition, because new data samples are written to the FIFO 130 more frequently than stored data samples are read from the FIFO 130, so there is no risk that a read operation will read invalid data from the FIFO 130 because the FIFO 130 is empty.

As in the data acquisition system 300, this allows the depth of the FIFO 130 to be reduced, in comparison to the system 100 described above with reference to FIGS. 1 and 2, as it is not necessary for the FIFO 130 to be half-full before a read operation can commence, and also permits a greater magnitude of spread spectrum modulation to be applied to the read clock signal for a given depth of the FIFO, without risk of FIFO overrun or FIFO underrun.

In some examples, a small delay of a predefined duration may be implemented following the start of spread spectrum modulation of the read clock signal before a read operation is permitted, to allow one or more data samples to be written to the FIFO 130 before a read operation commences. In such examples, the control circuitry 160 may maintain the read clock generator circuitry 150 in a deactivated or disabled state until a predefined delay period has elapsed after detection of the downward transition in the frequency frclk of the spread spectrum modulated read clock signal (or after the modulation control signal has been transmitted to the to the spread spectrum modulator circuitry 170). Once the predefined delay period has elapsed, the control circuitry 160 may activate or enable the read clock generator circuitry 150 (e.g. by transmitting an activate or enable signal to the read clock generator circuitry 150) to permit read operations to be performed.

In an alternative example, the control circuitry 160 and spread spectrum modulator circuitry 170 may be configured such that on commencement of the spread spectrum modulation of the frequency of the read clock signal, there is an upward transition in the frequency of the resulting spread spectrum modulated read clock signal, i.e. the frequency frclk rises above the mean frequency frclkmean. Thus, the start of data acquisition is synchronised or aligned in time with the upward transition in the frequency frclk of the spread spectrum modulated read clock signal.

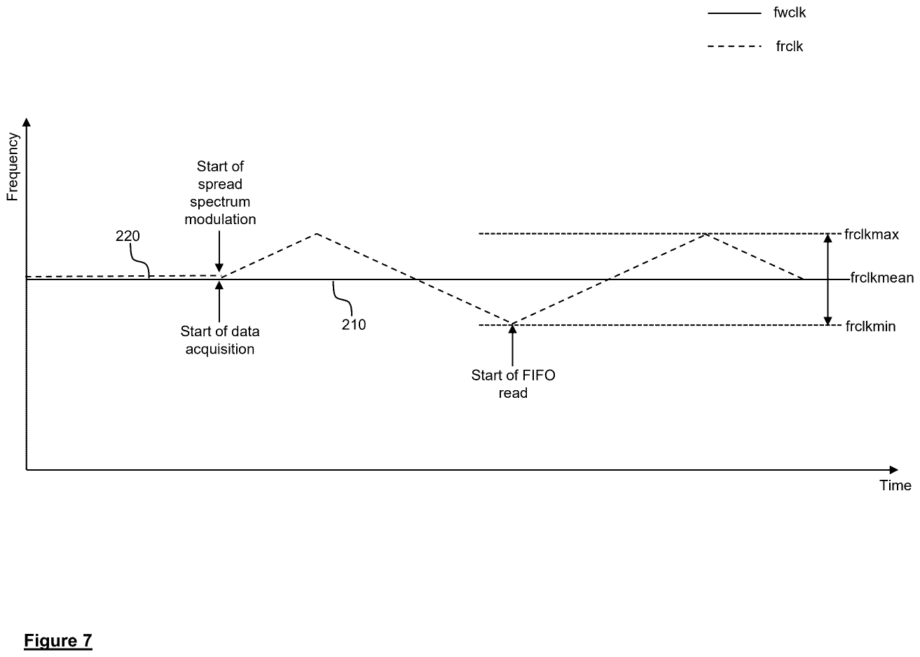

In such an example, as shown in FIG. 7, data acquisition begins at a point in time at which the frequency frclk of the spread spectrum modulated read clock signal is greater than the frequency fwclk of the write clock signal. Thus, to avoid a FIFO underrun condition, the start of a read operation to read data samples from the FIFO 130 should be delayed predefined delay period as shown in FIG. 7, e.g. until the FIFO 130 is at least half full.

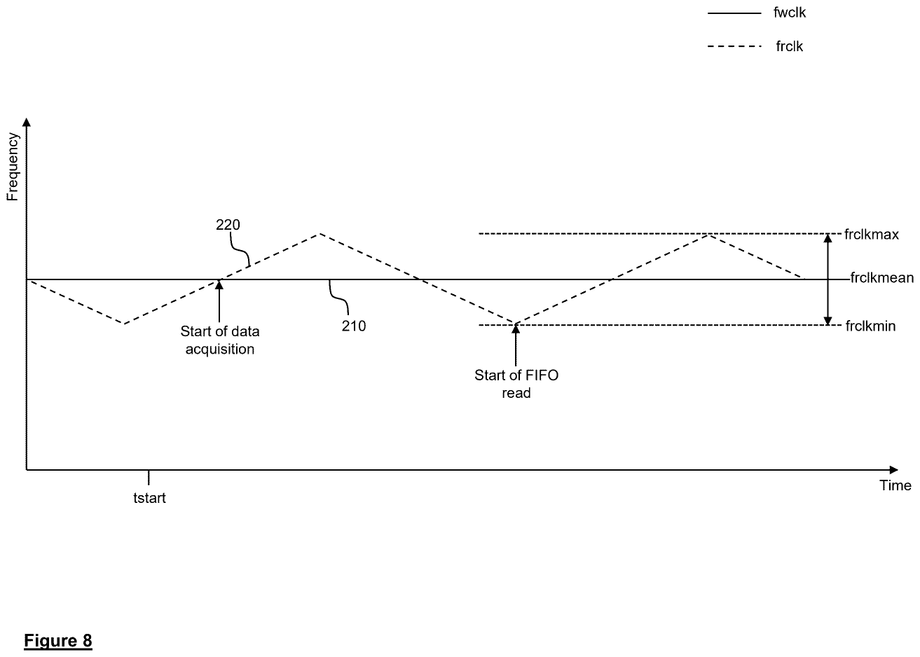

In a further example, the control circuitry 160 may be configured to synchronise or align in time the start of data acquisition with an upward transition in the frequency frclk of the spread spectrum modulated read clock signal, as shown in FIG. 8, by transmitting the Start signal to the ADC circuitry 110 or to the sample clock generator 120 to enable or activate the ADC circuitry 110 to allow the ADC circuitry 110 to begin outputting data samples to the FIFO 130 in response to detecting (e.g. based on a comparison of a value of the determined instant instantaneous frequency frclk of the spread spectrum modulated read clock signal to a value of the mean frequency frclkmean of the spread spectrum modulated read clock signal) the upward transition in the frequency frclk of the spread spectrum modulated read clock signal.

As in the exampled described above with reference to FIG. 7, in such an example, data acquisition begins at a point in time at which the frequency frclk of the spread spectrum modulated read clock signal is greater than the frequency fwclk of the write clock signal. Thus, to avoid a FIFO underrun condition, the start of a read operation to read data samples from the FIFO 130 should be delayed by a predefined delay period as shown in FIG. 8, e.g. until the FIFO 130 is at least half full.

In the examples described above with reference to FIGS. 7 and 8, the depth of the FIFO can be reduced, as compared to the example described above with reference to FIGS. 1 and 2, but a delay is required after the start of data acquisition before a read operation can commence, so latency may not be reduced, as compared to the example described above with reference to FIGS. 1 and 2.

The data acquisition systems 300, 500 described above with reference to FIGS. 3 and 5 respectively may each be implemented in integrated circuitry, e.g. as one or more integrated circuits.

The data acquisition systems described above with reference to the accompanying drawings may be incorporated in a host device such as a laptop, notebook, netbook or tablet computer, a gaming device such as a games console or a controller for a games console, a virtual reality (VR) or augmented reality (AR) device, a scanner, a mobile telephone, a portable audio player or some other portable device, or may be incorporated in an accessory device for use with a laptop, notebook, netbook or tablet computer, a gaming device, a VR or AR device, a mobile telephone, a portable audio player or other portable device.

The skilled person will recognise that some aspects of the above-described apparatus and methods may be embodied as processor control code, for example on a non-volatile carrier medium such as a disk, CD- or DVD-ROM, programmed memory such as read only memory (Firmware), or on a data carrier such as an optical or electrical signal carrier. For many applications embodiments of the invention will be implemented on a DSP (Digital Signal Processor), ASIC (Application Specific Integrated Circuit) or FPGA (Field Programmable Gate Array). Thus the code may comprise conventional program code or microcode or, for example code for setting up or controlling an ASIC or FPGA. The code may also comprise code for dynamically configuring re-configurable apparatus such as re-programmable logic gate arrays. Similarly the code may comprise code for a hardware description language such as Verilog TM or VHDL (Very high speed integrated circuit Hardware Description Language). As the skilled person will appreciate, the code may be distributed between a plurality of coupled components in communication with one another. Where appropriate, the embodiments may also be implemented using code running on a field-(re)programmable analogue array or similar device in order to configure analogue hardware.

Note that as used herein the term module shall be used to refer to a functional unit or block which may be implemented at least partly by dedicated hardware components such as custom defined circuitry and/or at least partly be implemented by one or more software processors or appropriate code running on a suitable general purpose processor or the like. A module may itself comprise other modules or functional units. A module may be provided by multiple components or sub-modules which need not be co-located and could be provided on different integrated circuits and/or running on different processors.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. A data acquisition system comprising:
sampling circuitry configured to output data samples;
write clock generator circuitry configured to generate a write clock signal having a predefined frequency;
read clock generator circuitry configured to generate a read clock signal;
spread spectrum modulator circuitry configured to modulate a frequency of the read clock signal, wherein a mean frequency of a resulting spread spectrum modulated read clock signal is equal to the predefined frequency of the write clock signal;
a first-in first-out memory (FIFO) configured such that data samples can be written to the FIFO in synchronisation with the write clock signal and data samples can be read from the FIFO in synchronisation with the read clock signal; and
control circuitry,
wherein the control circuitry is configured to synchronise commencement of data acquisition by the data acquisition system with a transition in the frequency of the spread spectrum modulated read clock signal from the mean frequency.

2. The data acquisition system of claim 1, wherein the transition in the frequency of the spread spectrum modulated read clock signal is a downward transition in the frequency of the spread spectrum modulated read clock signal from the mean frequency

3. The data acquisition system of claim 1, wherein the control circuitry is configured to trigger data acquisition by the data acquisition system responsive to detection of the transition.

4. The data acquisition system of claim 3, wherein the control circuitry is configured to detect the transition based on a signal indicative of a spread spectrum modulation frequency received from the spread spectrum modulator circuitry.

5. The data acquisition system of claim 4, wherein the control circuitry is configured to:
determine, based on the received signal indicative of a spread spectrum modulation frequency, an instantaneous frequency of the spread spectrum modulated read clock signal;
compare a value of the determined instantaneous frequency of the spread spectrum modulated read clock signal to a value of the mean frequency of the spread spectrum modulated read clock signal; and
responsive to detecting that the value of instantaneous frequency of the spread spectrum modulated read clock signal has fallen below the value of the mean frequency of the spread spectrum modulated read clock signal, trigger data acquisition by the data acquisition system.

6. The data acquisition system of claim 4, wherein the control circuitry is configured to:
determine, based on the received signal indicative of a spread spectrum modulation frequency, an instantaneous frequency of the spread spectrum modulated read clock signal;
compare a value of the determined instantaneous frequency of the spread spectrum modulated read clock signal to a value of the mean frequency of the spread spectrum modulated read clock signal; and
responsive to detecting that the value of instantaneous frequency of the spread spectrum modulated read clock signal has risen above the value of the mean frequency of the spread spectrum modulated read clock signal, trigger data acquisition by the data acquisition system.

7. The data acquisition system of claim 3, wherein the controller is configured to activate or enable the sampling circuitry to trigger data acquisition by the data acquisition system.

8. The data acquisition system of claim 1, wherein the sampling circuitry comprises analog to digital converter (ADC) circuitry configured to periodically sample a continuous input signal to generate output data samples.

9. The data acquisition system of claim 8, wherein the control circuitry is configured to trigger data acquisition by the data acquisition system on detection of the transition by enabling or activating the ADC circuitry.

10. The data acquisition system of claim 8, further comprising sample clock generator circuitry configured to supply a sample clock signal to the ADC circuitry.

11. The data acquisition system of claim 10, wherein the control circuitry is configured to trigger data acquisition by the data acquisition system on detection of the transition by enabling or activating the sample clock generator circuitry.

12. The data acquisition system of claim 3, wherein the control circuitry is configured to prevent reading of a data sample from the FIFO for a predetermined delay period following detection of the transition.

13. The data acquisition system of claim 1, wherein the control circuitry is configured to, responsive to receiving a signal indicating that data acquisition is to commence:
trigger modulation of the read clock signal by the spread spectrum modulator circuitry; and
activate or enable the sampling circuitry to trigger data acquisition by the data acquisition system.

14. The data acquisition system of claim 13, wherein the sampling circuitry comprises analog to digital converter (ADC) circuitry configured to periodically sample a continuous input signal to generate output data samples.

15. The data acquisition system of claim 14, wherein the control circuitry is configured to enable or activate the ADC circuitry to trigger data acquisition by the data acquisition system.

16. The data acquisition system of claim 14, further comprising sample clock generator circuitry configured to supply a sample clock signal to the ADC circuitry.

17. The data acquisition system of claim 15, wherein the control circuitry is configured to enable or activate the sample clock generator circuitry to enable or activate the ADC circuitry.

18. The data acquisition system of claim 13, wherein the control circuitry is configured to prevent reading of a data sample from the FIFO for a predetermined delay period following triggering modulation of the read clock signal by the spread spectrum modulator circuitry.

19. A data acquisition system comprising:
sampling circuitry configured to output data samples;
write clock generator circuitry configured to generate a write clock signal having a predefined frequency;
read clock generator circuitry;
spread spectrum modulator circuitry configured to modulate a frequency of the read clock signal to generate a spread spectrum modulated read clock signal, wherein a mean frequency of the spread spectrum modulated read clock signal is equal to the predefined frequency of the write clock signal;
a first-in first-out memory (FIFO) configured such that data samples can be written to the FIFO in synchronisation with the write clock signal and data samples can be read from the FIFO in synchronisation with the read clock signal;
and
control circuitry,
wherein the control circuitry is configured to trigger data acquisition by the data acquisition system responsive to detection of a transition in the frequency of the spread spectrum modulated read clock signal from the mean frequency.

20. A data acquisition system comprising:
sampling circuitry configured to output data samples;
write clock generator circuitry configured to generate a write clock signal having a predefined frequency;
read clock generator circuitry;
spread spectrum modulator circuitry operable to modulate a frequency of the read clock signal to generate a spread spectrum modulated read clock signal, wherein a mean frequency of the spread spectrum modulated read clock signal is equal to the predefined frequency of the write clock signal;
a first-in first-out memory (FIFO) configured such that data samples can be written to the FIFO in synchronisation with the write clock signal and data samples can be read from the FIFO in synchronisation with the read clock signal;
and
control circuitry,
wherein the control circuitry is configured to trigger operation of the spread spectrum modulator responsive to receiving a signal indicating that data acquisition is to commence.

21. An integrated circuit implementing the data acquisition system of claim 1.

22. A host device comprising the data acquisition system of claim 1, wherein the host device comprises a laptop, notebook, netbook or tablet computer, a gaming device, a games console, a controller for a games console, a virtual reality (VR) or augmented reality (AR) device, a scanner, a mobile telephone, a portable audio player, a portable device, an accessory device for use with a laptop, notebook, netbook or tablet computer, a gaming device, a games console a VR or AR device, a mobile telephone, a portable audio player or other portable device.

23. A data acquisition system comprising:
sampling circuitry configured to sample an input signal to generate output data samples;
an asynchronous first-in first-out memory (FIFO) for receiving data samples from the sampling circuitry; and
control circuitry,
wherein the control circuitry is configured to, responsive to receiving a signal indicating that data acquisition is to commence, delay generation of output data samples by the sampling circuitry until the FIFO can receive the output data samples without risk of FIFO overrun or FIFO underrun.
